(19) United States
(12) Patent Application Publication
(10) Pub. No.: US 2004/0098636 A1
(43) Pub. Date: May 20, 2004

(54) Setting up a procedure of a communication taking place between instances using a protocol tester

(76) Inventor: Christian Zander, Berlin (DE)

Correspondence Address: TEKTRONIX, INC., Francis I. Gray, MS 50-LAW, P.O. Box 500, Beaverton, OR, 97077, US

(21) Appl. No.: 10/692,504

(22) Filed: Oct. 24, 2003

(30) Foreign Application Priority Data
Nov. 15, 2002 (EP) 02025496.7

(51) Int. Cl. H03K 19/003

(52) U.S. Cl. 714/4

(57) ABSTRACT

Setting up a procedure of a communication taking place between at least two instances, with one instance being a protocol tester, includes the steps executable on the protocol tester of a) selecting the instances involved in the communication; b) selecting a protocol layer on the basis of which the communication between the selected instances is to take place; c) selecting abstract communication interfaces of the protocol layer which are involved in the communication; d) selecting communication data; e) setting up a communication procedure that is executable between the instances through the protocol tester on the basis of the selections, with the communications data selection being made graphically and with the parameters so selectable being allocated description files used for setting up the communication procedure that is executable between the instances, with the communications data selection being a graphic configuration of a communication sequence between the instances involved with a user being able to define within the communication data graphically a message from one instance to the other instance which contains a variable wherein the other instance performs one of several activities as a function of the content of the variable.

### BACKGROUND OF THE INVENTION

The present invention relates to testing a telecommunications network, and more particularly to setting up a procedure of a communication taking place between instances, one of which is a protocol tester.

Testing a telecommunications network using a protocol tester is known from EP 1 128 600 A 1 (U.S. patent application Pub. Ser. No. 2001/0,015,732 A1), which is incorporated herein by reference in its entirety. Using as an example the standardized MSC (Message Sequence Charts) language which serves to graphically display a communication procedure between two instances in a telecommunications network, the above-identified application explains the transformation of a graphic display into an executable version of a communication procedure. Details on MSC may be found in ITU-T Z 120, which is incorporated herein by reference in its entirety. This makes it possible even for users not skilled in the art of programming to easily create procedures. Thus the methodology described in EP 1 128 600 A 1 constitutes a major progress. Yet there remain problems which make the setting-up of a communication procedure with MSC awkward, which impede the readability of the generated code, and which entail a high storage demand. This is illustrated in the examples shown in FIGS. 1 to 3.

Based on the example of a repetition, FIG. 1 shows a communication procedure between the instance TC (Test Component) and the instance IUT (Item Under Test). The instance TC is formed by a protocol tester, while the instance IUT constitutes the unit to be tested. The task consists in the instance TC waiting for the setting up of a connection to be completed by the instance IUT. Thus, first the instance TC waits for the receipt of a dial tone and, upon receipt of such dial tone, sends out an inquiry as to whether the setting-up of the connection has been completed. If there is a reply from the IUT confirming that the setting-up of the connection is complete, the task ends. If, however, the IUT sends a reply that the setting-up of the connection is not yet complete, the TC continues to wait for the receipt of a dial tone. After receipt thereof, the TC again asks the question whether the setting-up of the connection is complete. If the TC receives an affirmative reply, the task is completed, but if not, the procedure of waiting and sending a completion inquiry continues until at some stage a programmer realizes that all relevant cases should be covered. Not an easy quest, as one can see, so the “ALT” boxes in FIG. 1 may continue downward several times more. This is extremely awkward and time-consuming, and impedes the readability of a longer communication procedure into which this task is incorporated.

FIG. 2 shows another prior art communication procedure where, upon receipt of event 2, the instance TC sends event 8. If one assumes that the communication sequence is contained in a number of communication procedures, and there results a change in the protocol development that, upon receipt of event 2, event 8 and event 9 are sent, then each individual chart has to be changed accordingly. This no doubt constitutes an error source if the change of individual charts is forgotten. Moreover, this takes a lot of time.

FIG. 3 shows a further prior art sequence of a communication procedure. The task is that, upon receipt of event 555, the instance TC sends event X. Upon receipt of all other events between 1 and 10,000, the instance TC sends nothing. Using this example, a certain message is sent only upon receipt of a certain telephone number. It is obvious that the programming effort for this task is immense, and the present situation is therefore unsatisfactory.

The alternative for avoiding awkward structures of this kind, as shown in FIGS. 1 and 2, is to incorporate boxes with a programming code into the charts. However, this entails a disadvantage which the invention described in EP 1 128 600 A1 avoided, i.e. that in order to define a communication procedure, the user has to have programming knowledge. For a known protocol tester, so-called Forth boxes, i.e. boxes with a programming code in the programming language Forth, would have to be incorporated into which the code would have to be programmed.

What is desired is to develop a generic method and a generic protocol tester in such a way that communication procedures may be set up with less programming effort, more clarity, swifter executability and less storage demand.

### BRIEF SUMMARY OF THE INVENTION

Accordingly the present invention uses a simplified communication procedure that makes actions of one of two instances of a communication procedure dependent, not on the receipt of events, but on the contents of variables. Rather than branchings being defined over events, a branching is a function of the content of a variable. A switch/case functionality may be specified, for example, which executes one instance as a function of the content of the variable. A loop functionality also may be realized as a function of the content of the variable. The loop functionality may also include a for-next, a do-while and/or a while-do functionality. Specifying jump and/or go-to functionalities and/or an if-then functionality as a function of the content of the variable also is possible. In a generic method, the instances involved in the communication are graphically selected, the protocol layer is graphically selected, and/or abstract communication interfaces of the protocol layer are graphically selected, with parameters so selected being allocated description files which are used subsequently for setting up the communication procedure executable between the instances, i.e. an executable script. The abstract communication interfaces may be SAPs (Service Access Points). The communication data may be PDUs (Protocol Data Units) and/or ASPs (Abstract Service Primitives). As part of the generic method partial steps of graphically selecting a data format and graphically setting up a communication sequence between the instances are involved. In the latter partial step a source code may be entered.

The objects, advantages and other novel features of the present invention are apparent from the following detailed description when read in conjunction with the appended claims and attached drawing.

### BRIEF DESCRIPTION OF THE SEVERAL VIEWS OF THE DRAWING

FIG. 1 is a chart view of a communication procedure for a repetition according to the prior art.

FIG. 2 is a chart view of a communication procedure according to the prior art where, upon receipt of event 2, event 8 is sent.

FIG. 3 is a chart view of a communication procedure according to the prior art where, upon receipt of event 555, event X is sent.

FIG. 4 is a chart view of a communication procedure according to the present invention corresponding to the communication procedure of FIG. 1.

FIG. 5 is a chart view of a communication procedure according to the present invention corresponding to a summary of the communication procedures of FIGS. 2 and 3.

FIG. 6 is a chart view of a communication procedure according to the present invention illustrating different switch functionalities.

FIG. 7 is a chart view of a communication procedure according to the present invention illustrating different loop functionalities.

### DETAILED DESCRIPTION OF THE INVENTION

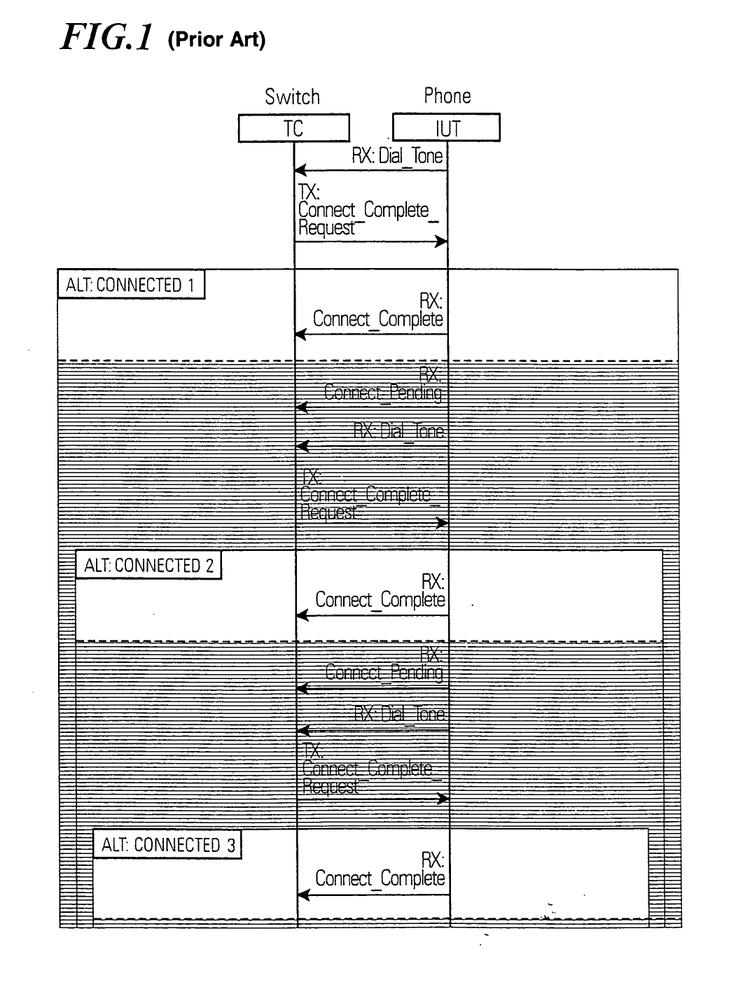

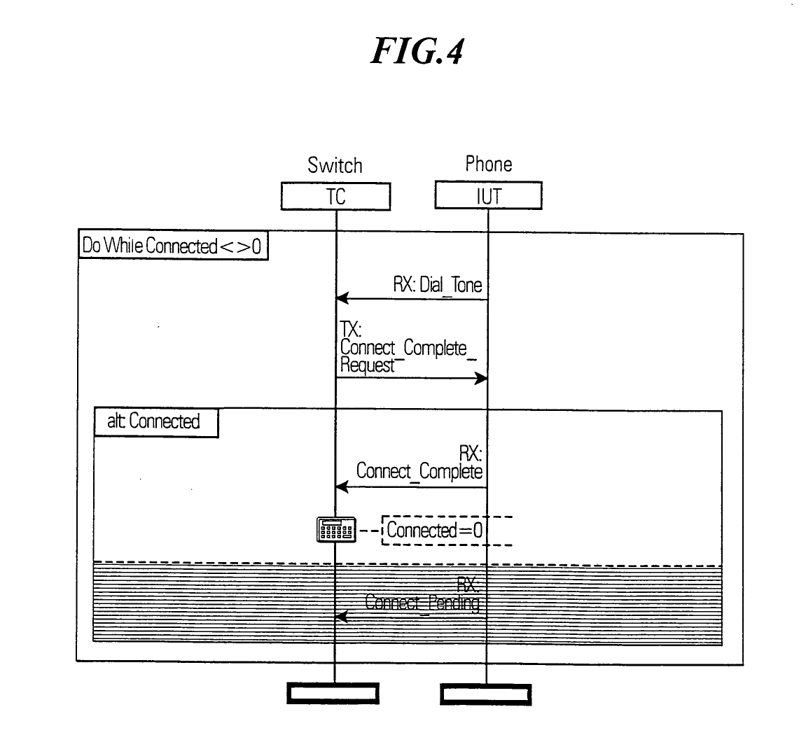

Referring now to FIG. 4 a do-while loop solves the same task as the communication procedure shown in FIG. 1, except that it is shorter and more clearly laid out. In the communication procedure illustrated in FIG. 4 the value of a “connected” variable is checked. As long as “connected” does not equal 0, the system waits for the next dial tone, which is followed by an inquiry as to whether the setting-up of the connection is complete. If this question is answered “yes”, then the “connected” variable is set to equal 0 and the task is fulfilled. If not, the “connected” variable is left unchanged so that the system continues in the do-while loop.

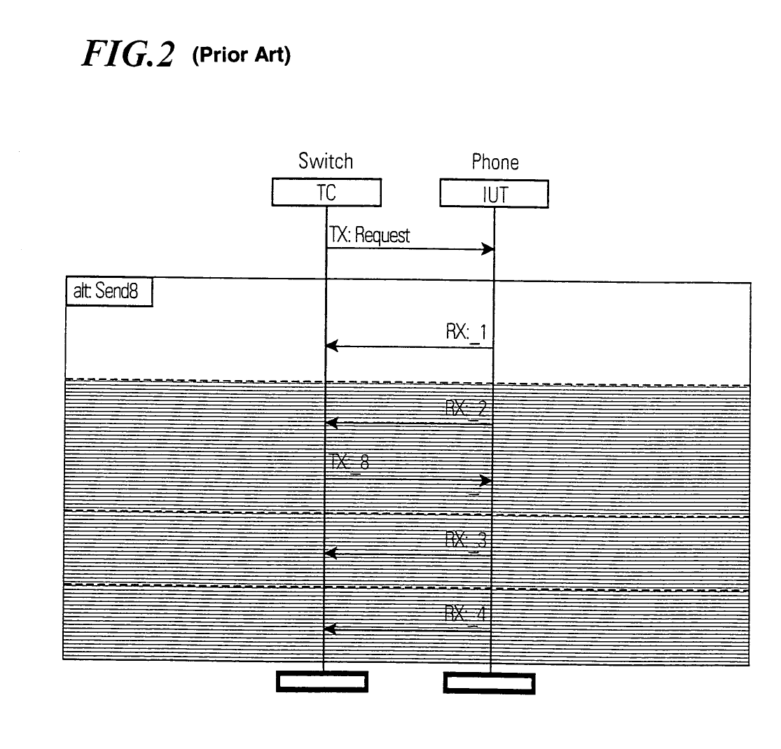

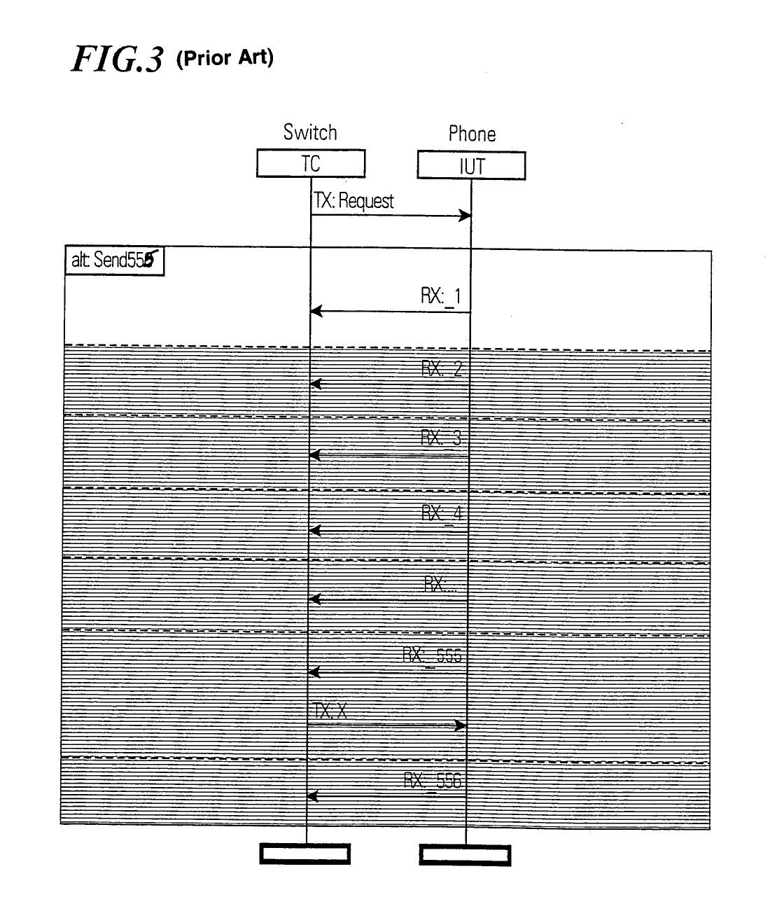

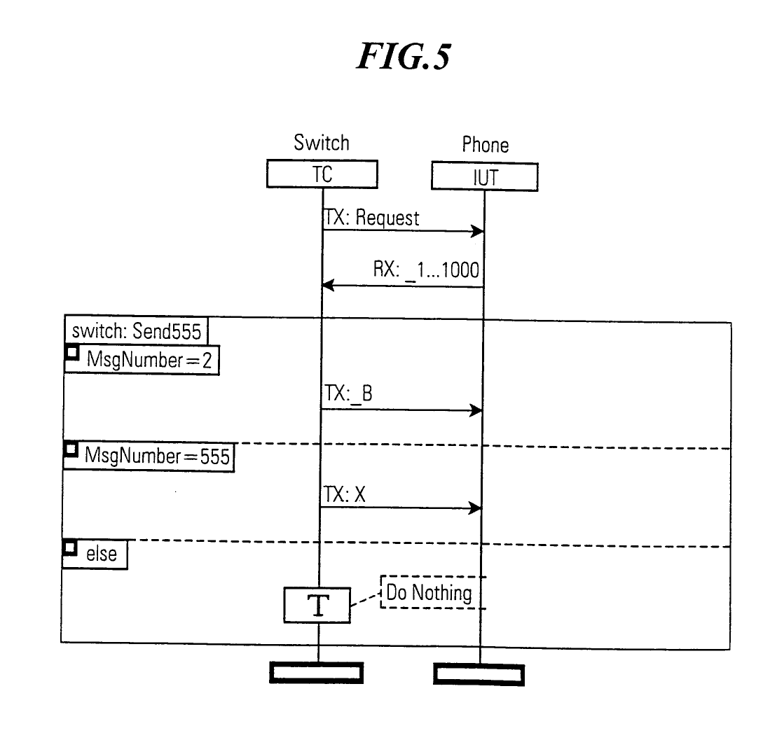

FIG. 5 shows how the tasks described in connection with FIGS. 2 and 3 are resolved according to the present invention. Having sent a request, the instance TC sends a message having a variable which can have a value of 1 to 1,000. Upon receipt of a message in which the variable MsgNumber has the value of 2, a message with the variable B is sent, while upon receipt of a message in which the MsgNumber has the value of 555, a message with the variable X is sent. In all another cases (“else” ) waiting only continues (“T” ). Instead of a change of all charts concerned, only variable B is allocated another value so that in the future, instead of event 8, events 8 and 9 are sent. Allocating another value once to variable B outside the charts is sufficient. All charts may thus remain unchanged. Another advantage is that, according to the prior art of FIGS. 2 and 3, as many messages had to be created as are required in order to resolve the measurement task, i.e. in the example case 1,000. In the solution of the present invention the generation of only a single message suffices for the present measurement task.

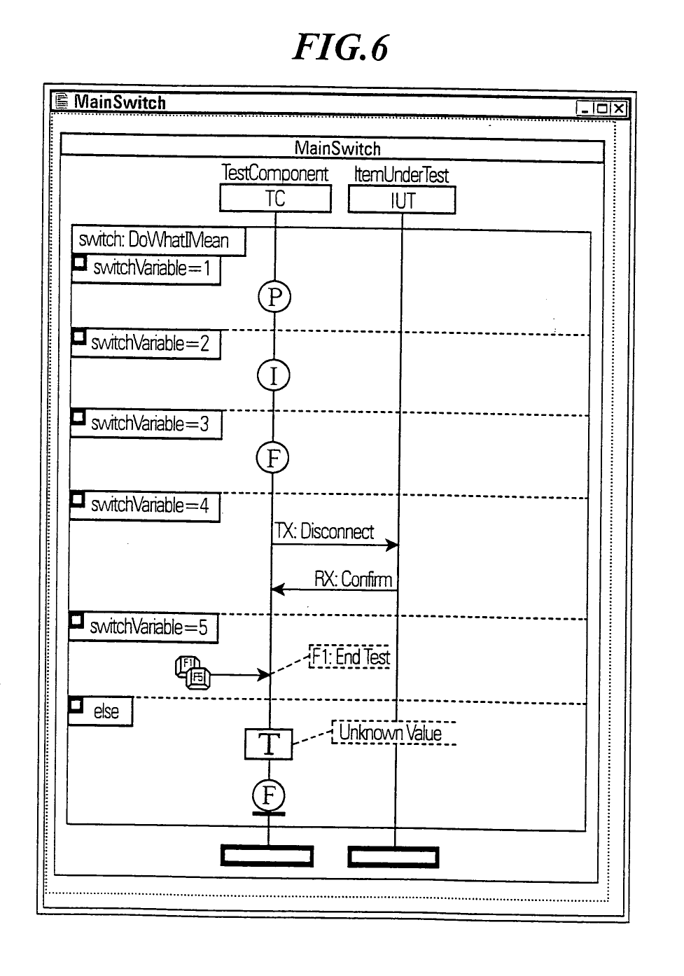

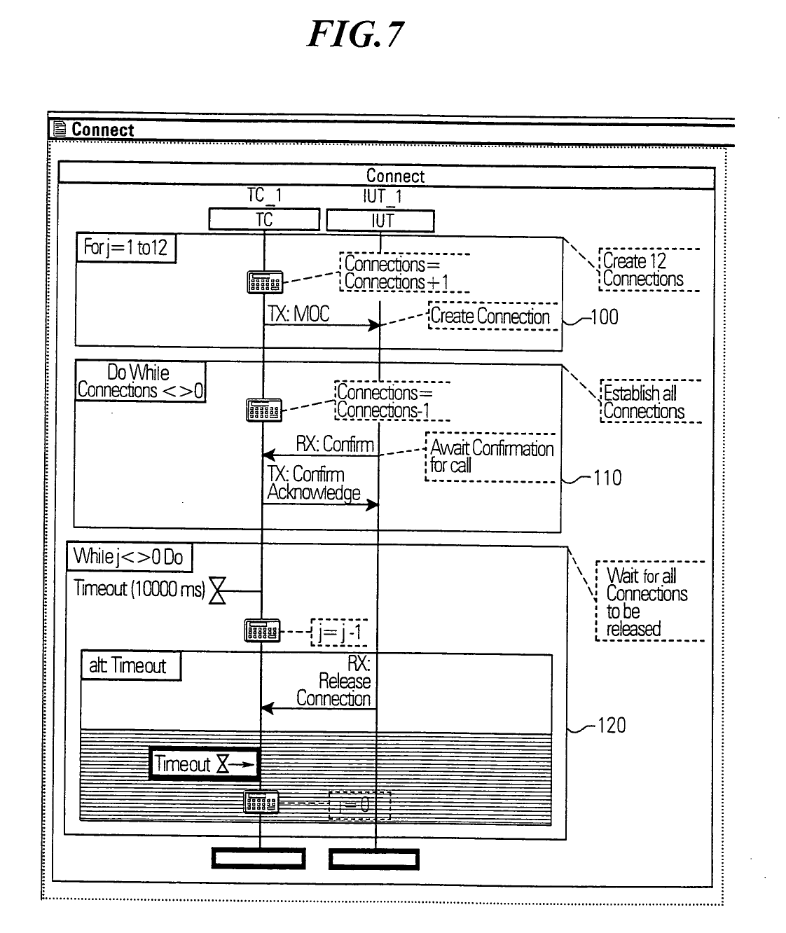

Annex A1 attached hereto shows an executable script according to the present invention for a switch function as illustrated in FIG. 6, while Annex A2 attached hereto shows an executable script according to the present invention which corresponds to a communication procedure illustrated in FIG. 7.

FIG. 6 shows an example of a switch/case functionality realized according to the present invention. Depending on the switch variables, various actions are performed by the protocol tester, i.e. the instance TC. If the switch variable equals 1, the message “passed” is issued. If the switch variable equals 2, the message “inconclusive”, i.e. “not coherent” is issued. If the switch variable equals 3, the message “failed” is issued. If the switch variable equals 4, a “disconnect” is sent and a “confirm” expected back. If the switch variable equals 5, the user is to press the F1 key to end the test. For all other values of the switch variable a trace text is shown, then a verdict, i.e. an evaluation of the test case is set and the test stopped. The associated code generated by the method is contained in Annex A1. The switch itself is handled by states 2 to 10, while state 11 is a jump-in point, and state 12 is an end point.

FIG. 7 shows various loop examples, with box 100 serving to generate 12 connections in accordance with a requirement “For j=1 to 12”. Box 110 is a loop with a verification at the end. The variable “connections” is reduced by 1 for each cycle, and passing through the loop continues for as long as the variable “connections” does not equal 0. Each time, the instance TC waits for the confirmation of a call and, when it has received the call, a call confirmation is sent. Box 120 shows a loop functionality in which the verification takes place at the beginning. As long as the variable does not equal 0, the system first waits for a 1 0-second timeout to elapse, after that the variable j is reduced by 1. In case a connection is terminated during the timeout, another timeout is set and then the variable j is set to equal 0. This function serves to wait until all connections have been released. In Annex A2 the code generated according to the present invention is printed. Such a code cannot be programmed in a Forth box because in a Forth box status transitions are not possible. This is because in each compilate the status numbers may change, e.g. as a result of an insertion, which requires a new status so that the status numbers shift. The result of this is that subsequent Forth boxes no longer function. Therefore, only a statistical code independent of the compilate may be entered into a Forth box.

While the present invention is described using the test description language MSC as an example, it can of course be applied to other description languages.

Thus the present invention provides setting up a procedure of a communication taking place between two instances where a protocol tester is one of the instances by selecting the instances involved in the communication; selecting a protocol layer on the basis of which the communication between the selected instances is to take place; selecting abstract communication interfaces of the protocol layer which are involved in the communication; selecting communication data; setting up a communication procedure that is executable between the instances through the protocol tester on the basis of the selections, with the communications data selection being made graphically and with the parameters so selectable being allocated description files used for setting up the communication procedure that is executable between the instances, with the communications data selection being a graphic configuration of a communication sequence between the instances involved with a user being able to define within the communication data graphically a message from one instance to the other instance which contains a variable wherein the other instance performs one of several activities as a function of the content of the variable.

```
ANNEX A1
( ***** Tektronix MSC-Linker <V2.3.0> builds scenario ‘SwitchDemo’ **-
*- forth -*-** )
: $MSC$_VersionDate c“ Oct 29 2002” ;
CREATE NO_DEFAULT_TM_INSTANCES
( >>>>>>>>>> Include initialization <<<<<<<<<< )
include pc:boot:/share/pfe/msc_header.4th
( >>>>>>>>>> Allocation <<<<<<<<<< )
( create instance variables and constants... )
1 CONSTANT MSC_NUM_OF_INSTANCES
CREATE $MSC$_InstanceVars MSC_NUM_OF_INSTANCES
$MSC$_ElemSize_InstanceVar * $MSC$_Allot&Erase
CREATE $MSC$_NextStateAddr MSC_NUM_OF_INSTANCES CELLS
$MSC$_Allot&Erase \ allocate memory for nextstate variables
CREATE $MSC$_DefaultFlagAddr MSC_NUM_OF_INSTANCES CELLS
$MSC$_Allot&Erase \ allocate memory for default state flags
CREATE $MSC$_DefaultReturnStateAddr MSC_NUM_OF_INSTANCES CELLS
$MSC$_Allot&Erase \ allocate memory for default state flags
CREATE $MSC$_DefaultStateAddr MSC_NUM_OF_INSTANCES CELLS
$MSC$_Allot&Erase \ allocate memory for default states
( create timer variables and constants... )
( TM0 )
( create environment function key variables and constants... )
12 CONSTANT $MSC$_FKEY#
CREATE $MSC$_FKeyAddr MSC_NUM_OF_INSTANCES $MSC$_FKEY# *
$MSC$_ElemSize_FKeyVar * $MSC$_Allot&Erase
( create pool variables and constants... )
1 CONSTANT MSC_NUM_OF_POOLS
CREATE $MSC$_PoolVars MSC_NUM_OF_POOLS CELLS $MSC$_Allot&Erase
( create message variables and constants... )
2 CONSTANT MSC_NUM_OF_MESSAGES
CREATE $MSC$_MsgVars MSC_NUM_OF_MESSAGES $MSC$_ElemSize_MsgVar *
$MSC$_Allot&Erase
1 CONSTANT MSC_NUM_OF_MSGDECODEVARS ( one per TM )
CREATE $MSC$_MsgDecodeVars MSC_NUM_OF_MSGDECODEVARS
$MSC$_ElemSize_MsgDecodeVar * $MSC$_Allot&Erase
2 CONSTANT MSC_NUM_OF_FOLDERS
CREATE $MSC$_MsgFolderVars MSC_NUM_OF_FOLDERS $MSC$_ElemSize_FolderVar
* $MSC$_Allot&Erase
CREATE $MSC$_EventStructureVars MSC_NUM_OF_POOLS MSC_NUM_OF_INSTANCES
* $MSC$_ElemSize_EventStructureVar * $MSC$_Allot&Erase
CREATE $MSC$_MsgSizeVars $MSC$_ElemSize_MsgSizeVar $MSC$_Allot&Erase
variable $MSC$_MsgMatched?
( create temporary variables and constants... )
variable $MSC$_TempFolderHandle
variable $MSC$_PDecoutVar
CREATE $MSC$_CurHMSCNameStringVar 255 ALLOT
CREATE $MSC$_TempStringVarAddr0 255 ALLOT
CREATE $MSC$_TempStringVarAddr1 255 ALLOT
CREATE $MSC$_TempStringVarAddr2 255 ALLOT
( create startstate variables... )
variable $MSC$_Req-State
( >>>>>>>>>> Test Managers <<<<<<<<<< )
12 TM_DEF_STATES !
0 TM_DEF_TIMERS !
0 $MSC$_TM_CREATE TM0
( >>>>>>>>>> Constants <<<<<<<<<< )
( create mapping of gateway name to poolindex )
0 constant MSC-GW-Gateway_1 \ Mapping Gatewayname ‘Gateway_1’ ->
Poolindex ‘0’
( create mapping of gateway name to SAP Index )
0 constant MSC-GW2SAP-Gateway_1 \ Mapping Gatewayname ‘Gateway_1’ ->
SAPIndex ‘0’
( >>>>>>>>>> Variables <<<<<<<<<< )
variable MSC-VAR-Gateway_1-connid
variable MSC-VAR-Gateway_1-Send_Sequence_Number_1
( >>>>>>>>>> Commands <<<<<<<<<< )
include pc:boot: /share/pfe/msc_lib.4th
( >>>>>>>>>> MSC ESE Variables <<<<<<<<<< )
: MSC_Var::MSC_String06 MSC_String6 ;
: MSC_Var::MSC_INT03 MSC_INT3 ;
: MSC_Var::MSC_String07 MSC_String7 ;
: MSC_Var::MSC_INT04 MSC_INT4 ;
: MSC_Var::MSC_String08 MSC_String8 ;
: MSC_Var::MSC_INT05 MSC_INT5 ;
: MSC_Var::MSC_String09 MSC_String9 ;
: MSC_Var::MSC_INT06 MSC_INT6 ;
: MSC_Var::MSC_INT07 MSC_INT7 ;
: MSC_Var::MSC_INT08 MSC_INT8 ;
: MSC_Var::MSC_INT09 MSC_INT9 ;
: MSC_Var::MSC_String01 MSC_String1 ;
: MSC_Var::MSC_String02 MSC_String2 ;
: MSC_Var::switchVariable MSC_INT0 ;
: MSC_Var::MSC_String03 MSC_String3 ;
: MSC_Var::MSC_String04 MSC_String4 ;
: MSC_Var::MSC_INT01 MSC_INT1 ;
: MSC_Var::MSC_String05 MSC_String5 ;
: MSC_Var::MSC_INT02 MSC_INT2 ;
MSC_NUM_OF_POOLS $MSC$_PoolPrepareInit
( constructor word ... )
: $MSC$_Constructor ( -- )
  0 $MSC$_PoolPrepareStart
  “ pc:C: /K1297/MBS-Pools/gsm2pa.pdc” 0 $MSC$_PoolOpen
  “ PROT<BSSM> send to EMUL<ss7sccp1>” 0 1 $MSC$_FolderOpen \ pool
‘pc:C:/K1297/MBS-Pools/gsm2pa.pdc’
  “ CONFIRM” 0 1 1 $MSC$_MsgVarInit \ pool ‘pc:C:/K1297/MBS-
Pools/gsm2pa.pdc’
  “ PROT<BSSM> send to EMUL<ss7sccp1>” 0 0 $MSC$_FolderOpen \ pool
‘pc:C:/K1297/MBS-Pools/gsm2pa.pdc’
  “ DISCONNECT_SCCP” 0 0 0 $MSC$_MsgVarInit \ pool ‘pc:C:/K1297/MBS-
Pools/gsm2pa.pdc’
  0 $MSC$_PoolPrepareExec
  MSC-VAR-Gateway_1-connid “ connid” “ PROT<DTAP_MSG> send to
EMUL<ss7sccp1>” 0 $MSC$_AssignMSCVar
  MSC-VAR-Gateway_1-Send_Sequence_Number_1 “ Send_Sequence_Number_1”
“ PROT<DTAP_MSG> send to EMUL<ss7sccp1>” 0 $MSC$_AssignMSCVar
  $MSC$_VerdictInit
  ;
( destructor word ... )
: $MSC$_Destructor ( -- )
        $MSC$_CloseAllPools
  ;
( >>>>>>>>>> Initialization <<<<<<<<<< )
0 0 $MSC$_InitMsg \ Create k12MBSevent structure for instance
‘TestComponent’ and gateway ‘Gateway_1’
TM0 ( >>>>>>>>>> start of instance ‘TestComponent’ <<<<<<<<<< )
( Segments of Instance ‘TestComponent’:
```

| Type | Segment Name | State | Length |
|---|---|---|---|
| INIT | - no name - | 0000000000 | 0000000001 |
| END | - no name - | 0000000001 | 0000000001 |
| DOC | MainSwitch | 0000000002 | 0000000008 |
| CONN | SwitchDemo/Start | 0000000010 | 0000000001 |
| CONN | SwitchDemo/MainSwitch | 0000000011 | 0000000001 |

```
  \ ----- init segment -----
  0 STATE_INIT{
      “ TM0 starts” “ TestComponent: ” 2 $MSC$_TraceControl
$MSC$_TraceMsgArray
      MSC_NUM_OF_INSTANCES $MSC$_VerdictReset \ init verdict
      0 $MSC$_ResetGotoModifierFlag \ init. instance
‘TestComponent’
      0 $MSC$_DefaultFlagSet
      0 $MSC$_DefaultStateSet
      ( switch command for startstate... )
      $MSC$_Req-State @ CASE
        1 OF 10 NEW_STATE ENDOF
      ENDCASE
  }STATE_INIT
  \ ----- end segment -----
  1 STATE_INIT{
      $MSC$_VerdictEval
      “ instance ‘TestComponent’ stops” $MSC$_PrintString
      “ TM0 stops” “ TestComponent: ” 2 $MSC$_TraceControl
$MSC$_TraceMsgArray
  }STATE_INIT
  1 STATE{
      ( this is the end state —loop forever )
  }STATE
  \ ----- document segment ‘MainSwitch’ -----
  2 STATE_INIT{
    ( start Switch ‘DoWhatIMean’ )
      $MSC$_ReturnStackAlmostFull? IF
        v. “ Error: Infinite recursion occured in State 2” vcr
        EXIT THEN
      ( MSC_INT0 = 1 IF )
      MSC_INT0 @
      1
      = IF
        3 0 $MSC$_NewState EXIT
        THEN
      ( MSC_INT0 = 2 IF )
      MSC_INT0 @
      2
      = IF
        4 0 $MSC$_NewState EXIT
        THEN
      ( MSC_INT0 = 3 IF )
      MSC_INT0 @
      3
      = IF
        5 0 $MSC$_NewState EXIT
        THEN
      ( MSC_INT0 = 4 IF )
      MSC_INT0 @
      4
      = IF
        6 0 $MSC$_NewState EXIT
        THEN
      ( MSC_INT0 = 5 IF )
      MSC_INT0 @
      5
      = IF
        8 0 $MSC$_NewState EXIT
        THEN
        ( else )
      TRUE IF
        9 0 $MSC$_NewState EXIT
        THEN
      ( end Switch ‘DoWhatIMean’ )
  }STATE_INIT
  3 STATE_INIT{
      “ Verdict set to value ‘pass’.” “ MainSwitch/TestComponent: ”
2 $MSC$_TraceVerdict $MSC$_TraceMsgArray
      $MSC$_VerdictPass
      $MSC$_DefaultFlagGet 0= IF
        0 $MSC$_GetNextState 0 $MSC$_NewState
      ELSE
        $MSC$_ReturnDefaultChart
      THEN
  }STATE_INIT
  4 STATE_INIT{
      “ Verdict set to value ‘inconclusive’.” “
MainSwitch/TestComponent: ” 2 $MSC$_TraceVerdict $MSC$_TraceMsgArray
      $MSC$_VerdictInconc
      $MSC$_DefaultFlagGet 0= IF
        0 $MSC$_GetNextState 0 $MSC$_NewState
      ELSE
        $MSC$_ReturnDefaultChart
      THEN
  }STATE_INIT
  5 STATE_INIT{
      “ Verdict set to value ‘fail’.” “ MainSwitch/TestComponent: ”
2 $MSC$_TraceVerdict $MSC$_TraceMsgArray
      $MSC$_VerdictFail
      $MSC$_DefaultFlagGet 0= IF
        0 $MSC$_GetNextState 0 $MSC$_NewState
      ELSE
        $MSC$_ReturnDefaultChart
      THEN
  }STATE_INIT
  6 STATE_INIT{
      “ Send message ‘DISCONNECT’ (‘PROT<BSSM> send to
EMUL<ss7sccp1>/DISCONNECT_SCCP’) to gateway ‘Gateway_1’ ” “
MainSwitch/TestComponent: ” 2 $MSC$_TraceSend $MSC$_TraceMsgArray
      “ DISCONNECT” 0 0 0 $MSC$_SendPrimitive
      7 0 $MSC$_NewState
  }STATE_INIT
  7 STATE{
    “ CONFIRM” 1 0 0 $MSC$_RecvPrimitive
    ACTION{
      “ Received message ‘CONFIRM’ (‘PROT<BSSM> send to
EMUL<ss7sccp1>/CONFIRM’) from gateway ‘Gateway_1’ ” “
MainSwitch/TestComponent: ” 2 $MSC$_TraceReceive $MSC$_TraceMsgArray
      0 0 1 $MSC$_FreeEventStructure \ free event structure of
message ‘CONFIRM’ (‘PROT<BSSM> send to EMUL<ss7sccp1>/CONFIRM’) and
gateway ‘Gateway_1’
      1 $MSC$_ResetMsgFlag \ message ‘CONFIRM’ (‘PROT<BSSM> send to
EMUL<ss7sccp1>/CONFIRM’) from gateway ‘Gateway_1’
      0 $MSC$_ResetGotoModifierFlag
      $MSC$_DefaultFlagGet 0= IF
        0 $MSC$_GetNextState 0 $MSC$_NewState
      ELSE
        $MSC$_ReturnDefaultChart
      THEN
    }ACTION
    TRUE
    ACTION{
      0 0 1 $MSC$_FreeEventStructure \ free event structure of
message ‘CONFIRM’ ( ‘PROT<BSSM> send to EMUL<ss7sccp1>/CONFIRM’) and
gateway ‘Gateway_1’
      $MSC$_CallDefaultChart
    }ACTION
  }STATE
  8 STATE{
    1 $MSC$_FKey?
    ACTION{
      “ Received environment input FK1 ” “
MainSwitch/TestComponent: “ 2 $MSC$_TraceEnvironment
$MSC$_TraceMsgArray
      1 $MSC$_ResetFKeyFlag
      0 $MSC$_ResetGotoModifierFlag
      $MSC$_DefaultFlagGet 0= IF
        0 $MSC$_GetNextState 0 $MSC$_NewState
      ELSE
        $MSC$_ReturnDefaultChart
      THEN
    }ACTION
    TRUE
    ACTION{
      $MSC$_CallDefaultChart
    }ACTION
  }STATE
  9 STATE_INIT{
      “ Unknown Value ” “ MainSwitch/TestComponent: ” 2
$MSC$_TraceUser $MSC$_TraceMsgArray
      “ Verdict set to value ‘fail’.” “ MainSwitch/TestComponent: ”
2 $MSC$_TraceVerdict $MSC$_TraceMsgArray
      $MSC$_VerdictFail
      $MSC$_CurHMSCNameStringVar “ TestComponent: ” 2
$MSC$_TraceControl $MSC$_TraceMsgArray
      1 0 $MSC$_SetNextState
      1 0 $MSC$_NewState
      EXIT
      $MSC$_DefaultFlagGet 0= IF
        0 $MSC$_GetNextState 0 $MSC$_NewState
      ELSE
        $MSC$_ReturnDefaultChart
      THEN
  }STATE_INIT
  \ ----- connector segment ‘SwitchDemo/Start’ -----
  10 STATE_INIT{
    “ Execution of HMSC ‘SwitchDemo’ started” “ TestComponent: ” 2
$MSC$_TraceControl $MSC$_TraceMsgArray
    “ SwitchDemo‘ finished” $MSC$_CurHMSCNameStringVar $MSC$_!String
    “ Execution of HMSC ’ ” $MSC$_CurHMSCNameStringVar
$MSC$_TempStringVarAddr0 $MSC$_StrCat
    11 0 $MSC$_SetNextState
    2 0 $MSC$_NewState
  }STATE_INIT
  \ ----- connector segment ‘SwitchDemo/MainSwitch’ -----
  11 STATE_INIT{
    “ Execution of HMSC ‘SwitchDemo’ finished” “ TestComponent: ” 2
$MSC$_TraceControl $MSC$_TraceMsgArray
    1 0 $MSC$_SetNextState
    1 0 $MSC$_NewState
  }STATE_INIT
( >>>>>>>>>> end of instance ‘TestComponent’ <<<<<<<<<< )
$MSC$_Constructor
MSC_MENU_CTRL_FCT ( calls the menu control function )
“ MSC scenario ‘SwitchDemo’ loaded” $MSC$_PrintString
```

```
ANNEX A2
( ***** Tektronix MSC-Linker <V2.3.0> builds scenario ‘Loo_Demo’ **-*-
forth -*-** )
: $MSC$_VersionDate c“ Oct 29 2002” ;
CREATE NO_DEFAULT_TM_INSTANCES
( >>>>>>>>>> Include initialization <<<<<<<<<< )
include pc:boot:/share/pfe/msc_header.4th
( >>>>>>>>>> Allocation <<<<<<<<<< )
( create instance variables and constants... )
1 CONSTANT MSC_NUM_OF_INSTANCES
CREATE $MSC$_InstanceVars MSC_NUM_OF_INSTANCES
$MSC$_ElemSize_InstanceVar * $MSC$_Allot&Erase
CREATE $MSC$_NextStateAddr MSC_NUM_OF_INSTANCES CELLS
$MSC$_Allot&Erase \ allocate memory for nextstate variables
CREATE $MSC$_DefaultFlagAddr MSC_NUM_OF_INSTANCES CELLS
$MSC$_Allot&Erase \ allocate memory for default state flags
CREATE $MSC$_DefaultReturnStateAddr MSC_NUM_OF_INSTANCES CELLS
$MSC$_Allot&Erase \ allocate memory for default state flags
CREATE $MSC$_DefaultStateAddr MSC_NUM_OF_INSTANCES CELLS
$MSC$_Allot&Erase \ allocate memory for default states
( create timer variables and constants... )
( TM0 )
0 10000 $MSC$_Timer_CREATE MSC_Timer::Timeout
( create environment function key variables and constants... )
12 CONSTANT $MSC$_FKEY#
CREATE $MSC$_FKeyAddr MSC_NUM_OF_INSTANCES $MSC$_FKEY# *
$MSC$_ElemSize_FKeyVar * $MSC$_Allot&Erase
( create pool variables and constants... )
1 CONSTANT MSC_NUM_OF_POOLS
CREATE $MSC$_PoolVars MSC_NUM_OF_POOLS CELLS $MSC$_Allot&Erase
( create message variables and constants... )
2 CONSTANT MSC_NUM_OF_MESSAGES
CREATE $MSC$_MsgVars MSC_NUM_OF_MESSAGES $MSC$_ElemSize_MsgVar *
$MSC$_Allot&Erase
1 CONSTANT MSC_NUM_OF_MSGDECODEVARS ( one per TM )
CREATE $MSC$_MsgDecodeVars MSC_NUM_OF_MSGDECODEVARS
$MSC$_ElemSize_MsgDecodeVar * $MSC$_Allot&Erase
2 CONSTANT MSC_NUM_OF_FOLDERS
CREATE $MSC$_MsgFolderVars MSC_NUM_OF_FOLDERS $MSC$_ElemSize_FolderVar
* $MSC$_Allot&Erase
CREATE $MSC$_EventStructureVars MSC_NUM_OF_POOLS MSC_NUM_OF_INSTANCES
* $MSC$_ElemSize_EventStructureVar * $MSC$_Allot&Erase
CREATE $MSC$_MsgSizeVars $MSC$_ElemSize_MsgSizeVar $MSC$_Allot&Erase
variable $MSC$_MsgMatched?
( create temporary variables and constants... )
variable $MSC$_TempFolderHandle
variable $MSC$_PDecoutVar
2 CONSTANT MSC_NUM_OF_TMPVARS
CREATE $MSC$_TmpVars MSC_NUM_OF_TMPVARS CELLS $MSC$_Allot&Erase
CREATE $MSC$_CurHMSCNameStringVar 255 ALLOT
CREATE $MSC$_TempStringVarAddr0 255 ALLOT
CREATE $MSC$_TempStringVarAddr1 255 ALLOT
CREATE $MSC$_TempStringVarAddr2 255 ALLOT
( create startstate variables... )
variable $MSC$_Req-State
( >>>>>>>>>> Test Managers <<<<<<<<<< )
17 TM_DEF_STATES !
1 TM_DEF_TIMERS !
0 $MSC$_TM_CREATE TM0
( >>>>>>>>>> Constants <<<<<<<<<< )
( create mapping of gateway name to poolindex )
0 constant MSC-GW-Gateway_1 \ Mapping Gatewayname ‘Gateway_1’ ->
Poolindex ‘0’
( create mapping of gateway name to SAP Index )
0 constant MSC-GW2SAP-Gateway_1 \ Mapping Gatewayname ‘Gateway_1’ ->
SAPIndex ‘0’
( >>>>>>>>>> Variables <<<<<<<<<< )
variable MSC-VAR-Gateway_1-Service_Key_1
( >>>>>>>>>> Commands <<<<<<<<<< )
include pc:boot:/share/pfe/msc_lib.4th
( >>>>>>>>>> MSC ESE Variables <<<<<<<<<< )
: MSC_Var::MSC_String06 MSC_String6 ;
: MSC_Var::MSC_INT03 MSC_INT3 ;
: MSC_Var::MSC_String07 MSC_String7 ;
: MSC_Var::MSC_INT04 MSC_INT4 ;
: MSC_Var::MSC_String08 MSC_String8 ;
: MSC_Var::MSC_INT05 MSC_INT5 ;
: MSC_Var::MSC_String09 MSC_String9 ;
: MSC_Var::MSC_INT06 MSC_INT6 ;
: MSC_Var::MSC_INT07 MSC_INT7 ;
: MSC_Var::j MSC_INT0 ;
: MSC_Var::MSC_INT08 MSC_INT8 ;
: MSC_Var::MSC_INT09 MSC_INT9 ;
: MSC_Var::Connections MSC_INT1 ;
: MSC_Var::MSC_String01 MSC_String1 ;
: MSC_Var::MSC_String02 MSC_String2 ;
: MSC_Var::MSC_String03 MSC_String3 ;
: MSC_Var::MSC_String04 MSC_String4 ;
: MSC_Var::MSC_String05 MSC_String5 ;
: MSC_Var::MSC_INT02 MSC_INT2 ;
MSC_NUM_OF_POOLS $MSC$_PoolPrepareInit
( constructor word ... )
: $MSC$_Constructor ( -- )
  0 $MSC$_PoolPrepareStart
  “ pc:C:/K1297/MBS-Pools/camel1a.pdc” 0 $MSC$_PoolOpen
  “ PROT<CAP> send to EMUL<ss7sccp1>” 0 1 $MSC$_FolderOpen \ pool
‘pc:C:/K1297/MBS-Pools/camel1a.pdc’
  “ SCCP_END_Connect” 0 1 1 $MSC$_MsgVarInit \ pool ‘pc:C:/K1297/MBS-
Pools/camel1a.pdc’
  “ PROT<CAP> send to EMUL<ss7sccp1>” 0 0 $MSC$_FolderOpen \ pool
‘pc:C:/K1297/MBS-Pools/camel1a.pdc’
  “ SCCP_START” 0 0 0 $MSC$_MsgVarInit \ pool ‘pc:C:/K1297/MBS-
Pools/camel1a.pdc’
  0 $MSC$_PoolPrepareExec
  MSC-VAR-Gateway_1-Service_Key_1 “ Service_Key_1” “ PROT<CAP> send
to EMUL<ss7sccp1>” 0 $MSC$_AssignMSCVar
  $MSC$_VerdictInit
  ;
( destructor word ... )
: $MSC$_Destructor ( -- )
        $MSC$_CloseAllPools
  ;
( >>>>>>>>>> Initialization <<<<<<<<<< )
0 0 $MSC$_InitMsg \ Create k12MBSevent structure for instance ‘TC_1’
and gateway ‘Gateway_1’
TM0 ( >>>>>>>>>> start of instance ‘TC_1’ <<<<<<<<<< )
( Segments of Instance ‘TC_1’:
```

| Type | Segment Name | State | Length |
|---|---|---|---|
| INIT | - no name - | 0000000000 | 0000000001 |
| END | - no name - | 0000000001 | 0000000001 |
| DOC | Connect | 0000000002 | 0000000013 |
| CONN | Loo_Demo/Start | 0000000015 | 0000000001 |
| CONN | Loo_Demo/Connect | 0000000016 | 0000000001 |

```
  \ ----- init segment -----
  0 STATE_INIT{
      “ TM0 starts” “ TC_1: ” 2 $MSC$_TraceControl
$MSC$_TraceMsgArray
      MSC_NUM_OF_INSTANCES $MSC$_VerdictReset \ init verdict
      0 $MSC$_ResetGotoModifierFlag \ init. instance ‘TC_1’
      0 $MSC$_DefaultFlagSet
      0 $MSC$_DefaultStateSet
      MSC_Timer::Timeout $MSC$_Timer_Init \ init. timer ‘Timeout’
      ( switch command for startstate... )
      $MSC$_Req-State @ CASE
        1 OF 15 NEW_STATE ENDOF
      ENDCASE
  }STATE_INIT
  \ ----- end segment -----
  1 STATE_INIT{
      $MSC$_VerdictEval
      “ instance ‘TC_1’ stops” $MSC$_PrintString
      “ TM0 stops” “ TC_1: ” 2 $MSC$_TraceControl
$MSC$_TraceMsgArray
  }STATE_INIT
  1 STATE{
      ( this is the end state - loop forever )
  }STATE
  \ ----- document segment ‘Connect’ -----
  2 STATE_INIT{
      12 MSC_INT0 !
      12 0 $MSC$_DefaultFlagGet + $MSC$_SetTmpVar
      3 0 $MSC$_NewState
  }STATE_INIT
  3 STATE_INIT{
      “ Desktop Calculator ‘Connections = Connections + 1’ start ”
“ Connect/TC_1: ” 2 $MSC$_TraceDCalculator $MSC$_TraceMsgArray
      ( start Desktop Calculator ‘Connections = Connections + 1’ )
        ( Connections = Connections + 1 )
        MSC_INT1 @
        1
        $MSC$_+
        MSC_INT1 !
      ( end Desktop Calculator ‘Connections = Connections + 1’ )
      “ Desktop Calculator ‘Connections = Connections + 1’ end ” “
Connect/TC_1: ” 2 $MSC$_TraceDCalculator $MSC$_TraceMsgArray
      “ Send message ‘MOC’ (‘PROT<CAP> send to
EMUL<ss7sccp1>/SCCP_START’) to gateway ‘Gateway_1’ ” “ Connect/TC_1: ”
2 $MSC$_TraceSend $MSC$_TraceMsgArray
      “ MOC” 0 0 0 $MSC$_SendPrimitive
      4 0 $MSC$_NewState
  }STATE_INIT
  4 STATE_INIT{
    $MSC$_ReturnStackAlmostFull? IF
      “ WARNING: Infinite recursion occured in repetition in chart
‘Connect’ - continue with next state...”
      0 $MSC$_GetNextState 0 $MSC$_NewState EXIT
    THEN
      MSC_INT0 @ 1 − MSC_INT0 !
      MSC_INT0 @ 0 <> IF
        3 0 $MSC$_NewState EXIT
      ELSE
        5 0 $MSC$_NewState EXIT
      THEN
  }STATE_INIT
  5 STATE_INIT{
      6 0 $MSC$_NewState
  }STATE_INIT
  6 STATE_INIT{
      “ Desktop Calculator ‘Connections = Connections − 1’ start ”
“ Connect/TC_1: ” 2 $MSC$_TraceDCalculator $MSC$_TraceMsgArray
      ( start Desktop Calculator ‘Connections = Connections − 1’ )
        ( Connections = Connections − 1 )
        MSC_INT1 @
        1
        $MSC$_−
        MSC_INT1 !
      ( end Desktop Calculator ‘Connections = Connections − 1’ )
      “ Desktop Calculator ‘Connections = Connections − 1’ end ” “
Connect/TC_1: ” 2 $MSC$_TraceDCalculator $MSC$_TraceMsgArray
      7 0 $MSC$_NewState
  }STATE_INIT
  7 STATE{
    “ Confirm” 1 0 0 $MSC$_RecvPrimitive
    ACTION{
      “ Received message ‘Confirm’ (‘PROT<CAP> send to
EMUL<ss7sccp1>/SCCP_END_Connect’) from gateway ‘Gateway_1’ ” “
Connect/TC_1: ” 2 $MSC$_TraceReceive $MSC$_TraceMsgArray
      0 0 1 $MSC$_FreeEventStructure \ free event structure of
message ‘Confirm’ (‘PROT<CAP> send to
EMUL<ss7sccp1>/SCCP_END_Connect’) and gateway ‘Gateway_1’
      1 $MSC$_ResetMsgFlag \ message ‘Confirm’ (‘PROT<CAP> send to
EMUL<ss7sccp1>/SCCP_END_Connect’) from gateway ‘Gateway_1’
      0 $MSC$_ResetGotoModifierFlag
      “ Send message ‘ConfirmAcknowledge’ (‘PROT<CAP> send to
EMUL<ss7sccp1>/SCCP_START’) to gateway ‘Gateway_1’ ” “ Connect/TC_1: ”
2 $MSC$_TraceSend $MSC$_TraceMsgArray
      “ ConfirmAcknowledge” 0 0 0 $MSC$_SendPrimitive
      8 0 $MSC$_NewState
    }ACTION
    TRUE
    ACTION{
      0 0 1 $MSC$_FreeEventStructure \ free event structure of
message ‘Confirm’ (‘PROT<CAP> send to
EMUL<ss7sccp1>/SCCP_END_Connect’) and gateway ‘Gateway_1’
      $MSC$_CallDefaultChart
    }ACTION
  }STATE
  8 STATE_INIT{
    $MSC$_ReturnStackAlmostFull? IF
      “ WARNING: Infinite recursion occured in repetition in chart
‘Connect’ - continue with next state...”
      0 $MSC$_GetNextState 0 $MSC$_NewState EXIT
    THEN
      MSC_INT1 @ 0 <> IF
        6 0 $MSC$_NewState EXIT
      ELSE
        9 0 $MSC$_NewState EXIT
      THEN
  }STATE_INIT
  9 STATE_INIT{
      14 0 $MSC$_NewState
  }STATE_INIT
  10 STATE_INIT{
      “ Timer ‘Timeout’ set with value 10000” “ Connect/TC_1: ” 2
$MSC$_TraceTimer $MSC$_TraceMsgArray
      10000 MSC_Timer::Timeout $MSC$_Timer_RunTime!
      MSC_Timer::Timeout $MSC$_Timer_Start \ timer ‘Timeout’
      “ Desktop Calculator ‘j = j − 1’ start ” “ Connect/TC_1: ” 2
$MSC$_TraceDCalculator $MSC$_TraceMsgArray
      ( start Desktop Calculator ‘j = j − 1’ )
        ( j = j − 1 )
        MSC_INT0 @
        1
        $MSC$_-
        MSC_INT0 !
      ( end Desktop Calculator ‘j = j − 1’ )
      “ Desktop Calculator ‘j = j − 1’ end ” “ Connect/TC_1: ” 2
$MSC$_TraceDCalculator $MSC$_TraceMsgArray
      11 0 $MSC$_NewState
  }STATE_INIT
  11 STATE_INIT{
      1 $MSC$_ResetMsgFlag \ message ‘ReleaseConnection’
(‘PROT<CAP> send to EMUL<ss7sccp1>/SCCP_END_Connect’) from gateway
‘Gateway_1’
  }STATE_INIT
  11 STATE{
    “ ReleaseConnection” 1 0 0 $MSC$_RecvPrimitive
    ACTION{
      0 0 1 $MSC$_FreeEventStructure \ free event structure of
message ‘ReleaseConnection’ (‘PROT<CAP> send to
EMUL<ss7sccp1>/SCCP_END_Connect’) and gateway ‘Gateway_1’
      0 $MSC$_SetGotoModifierFlag
      12 0 $MSC$_NewState
    }ACTION
    “ TC_1” “ Timeout” MSC_Timer::Timeout $MSC$_Timer_Timeout?
    ACTION{
      0 0 1 $MSC$_FreeEventStructure \ free event structure of
message ‘ReleaseConnection’ (‘PROT<CAP> send to
EMUL<ss7sccp1>/SCCP_END_Connect’) and gateway ‘Gateway_1’
      0 $MSC$_SetGotoModifierFlag
      13 0 $MSC$_NewState
    }ACTION
    TRUE
    ACTION{
      0 0 1 $MSC$_FreeEventStructure \ free event structure of
message ‘ReleaseConnection’ (‘PROT<CAP> send to
EMUL<ss7sccp1>/SCCP_END_Connect’) and gateway ‘Gateway_1’
      $MSC$_CallDefaultChart
    }ACTION
  }STATE
  12 STATE{
    “ ReleaseConnection” 1 0 0 $MSC$_RecvPrimitive
    ACTION{
      “ Received message ‘ReleaseConnection’ (‘PROT<CAP> send to
EMUL<ss7sccp1>/SCCP_END_Connect’) from gateway ‘Gateway_1’ ” “
Connect/TC_1: ” 2 $MSC$_TraceReceive $MSC$_TraceMsgArray
      0 0 1 $MSC$_FreeEventStructure \ free event structure of
message ‘ReleaseConnection’ (‘PROT<CAP> send to
EMUL<ss7sccp1>/SCCP_END_Connect’) and gateway ‘Gateway_1’
      1 $MSC$_ResetMsgFlag \ message ‘ReleaseConnection’
(‘PROT<CAP> send to EMUL<ss7sccp1>/SCCP_END_Connect’) from gateway
‘Gateway_1’
      0 $MSC$_ResetGotoModifierFlag
      14 0 $MSC$_NewState
    }ACTION
    TRUE
    ACTION{
      0 0 1 $MSC$_FreeEventStructure \ free event structure of
message ‘ReleaseConnection’ (‘PROT<CAP> send to
EMUL<ss7sccp1>/SCCP_END_Connect’) and gateway ‘Gateway_1’
      $MSC$_CallDefaultChart
    }ACTION
  }STATE
  13 STATE{
    “ TC_1” “ Timeout” MSC_Timer::Timeout $MSC$_Timer_Timeout?
    ACTION{
      “ Received timeout ‘Timeout’ ” “ Connect/TC_1: ” 2
$MSC$_TraceTimer $MSC$_TraceMsgArray
      0 $MSC$_ResetGotoModifierFlag
      “ Desktop Calculator ‘j = 0’ start ” “ Connect/TC_1: ” 2
$MSC$_TraceDCalculator $MSC$_TraceMsgArray
      ( start Desktop Calculator ‘j = 0’ )
        ( j = 0 )
        0
        MSC_INT0 !
      ( end Desktop Calculator ‘j = 0’ )
      “ Desktop Calculator ‘j = 0’ end ” “ Connect/TC_1: ” 2
$MSC$_TraceDCalculator $MSC$_TraceMsgArray
      14 0 $MSC$_NewState
    }ACTION
    TRUE
    ACTION{
      $MSC$_CallDefaultChart
    }ACTION
  }STATE
  14 STATE_INIT{
    $MSC$_ReturnStackAlmostFull? IF
      “ WARNING: Infinite recursion occured in repetition in chart
‘Connect’ - continue with next state...”
      0 $MSC$_GetNextState 0 $MSC$_NewState EXIT
    THEN
      MSC_INT0 @ 0 <> IF
        10 0 $MSC$_NewState EXIT
      ELSE
        $MSC$_DefaultFlagGet 0= IF
          0 $MSC$_GetNextState 0 $MSC$_NewState EXIT
        ELSE
          $MSC$_ReturnDefaultChart EXIT
        THEN
      THEN
  }STATE_INIT
  \ ----- connector segment ‘Loo_Demo/Start’ -----
  15 STATE_INIT{
    “ Execution of HMSC ‘Loo_Demo’ started” “ TC_1: ” 2
$MSC$_TraceControl $MSC$_TraceMsgArray
    “ Loo_Demo‘ finished” $MSC$_CurHMSCNameStringvar $MSC$_!String
    “ Execution of HMSC ’” $MSC$_CurHMSCNameStringVar
$MSC$_TempStringVarAddr0 $MSC$_StrCat
    16 0 $MSC$_SetNextState
    2 0 $MSC$_NewState
  }STATE_INIT
  \ ----- connector segment ‘Loo_Demo/Connect’ -----
  16 STATE_INIT{
    “ Execution of HMSC ‘Loo_Demo’ finished” “ TC_1: ” 2
$MSC$_TraceControl $MSC$_TraceMsgArray
    1 0 $MSC$_SetNextState
    1 0 $MSC$_NewState
  }STATE_INIT
( >>>>>>>>>> end of instance ‘TC_1’ <<<<<<<<<< )
$MSC$_Constructor
MSC_MENU_CTRL_FCT ( calls the menu control function )
“ MSC scenario ‘Loo_Demo’ loaded” $MSC$_PrintString
```

What is claimed is:

1. A method of setting up a procedure of a communication taking place between two instances, with one instance being a protocol tester and the other instance being a device under test, comprising the steps executable on the protocol tester of:
a) selecting the instances involved in the communication;
b) selecting a protocol layer on the basis of which the communication between the selected instances is to take place;
c) selecting abstract communication interfaces of the protocol layer which are involved in the communication;
d) selecting communication data;
e) setting up a communication procedure executable between the instances through the protocol tester on the basis of the several selecting steps with the selection of the communication data being made graphically and with the parameters so selectable being allocated description files which are used for setting up the communication procedure that is executable between the instances, with further with the communication data selecting step including a graphic configuration of a communication sequence between the instances involved; and
f) defining within the communication data graphically a message from one instance to the other instance which contains a variable wherein the other instance performs one of several activities as a function of the content of the variable.

2. The method according to claim 1 further comprising the step of specifying a switch functionality which the other instance executes as a function of the content of the variable.

3. The method according to claims 1 or 2 further comprising the step of specifying a loop functionality which the other instance executes as a function of the content of the variable.

4. The method according to claim 3 wherein the loop functionality is selected from the group consisting of a for-next, a do-while and a while-do functionality.

5. The method according to claim 3 further comprising the step of specifying a functionality selected from the group consisting of a jump/go-to functionality and an if-then functionality which the other instance executes as a function of the content of the variable.

6. The method according to claim 1 wherein the instances involved in the communication are graphically selected, the protocol layer is graphically selected, and the abstract communication interfaces are graphically selected.

7. The method according to claim 1 wherein the abstract communication interfaces comprise SAPs (Service Access Points).

8. The method according to claim 1 wherein the communication data comprise data selected from the group consisting of PDUs (Protocol Data Units) and ASPs (Abstract Service Primitives).

9. The method according to claim 1 wherein the communication data selecting step comprises the steps of:
d1) graphically selecting a data format; and
d2) graphically setting up the communication sequence between the instances involved.

10. The method according to claim 9 wherein the communication sequence setting up step comprises the step of entering source code.

11. A protocol tester comprising:
a) means for selecting instances involved in a communication, with one of the instances being the protocol tester and the other being a device under test;
b) means for selecting a protocol layer on the basis of which the communication between the selected instances is to take place;
c) means for selecting abstract communication interfaces of the protocol layer which are involved in the communication;
d) means for selecting communication data;
e) means for automatically setting up a communication procedure that is executable between the instances through the protocol tester on the basis of the selections by the several selecting means, with the communications data selecting means being a graphic selection means and with the parameters selectable by them being allocated description files which may be used by the setting-up means for setting up the communication procedure that is executable between the instances which makes the setting-up of a communication sequence between the instances involved possible; and
means for defining within the communication data graphically a message from one instance to the other instance which contains a variable wherein the other instance performs one of several activities as a function of the content of the variable.
